(19) United States
(12) Patent Application Publication
(10) Pub. No.: US 2006/0158064 A1
(43) Pub. Date: Jul. 20, 2006

(54) Piezoelectric sounding body and electronic device

(76) Inventors: Kazuo Asakawa, Gunma (JP); Tatsuyuki Ogawa, Gunma (JP); Yasukazu Tokuhisa, Gunma (JP); Yoshiyuki Watanabe, Gunma (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/291,739

(22) Filed: Dec. 1, 2005

(30) Foreign Application Priority Data
Dec. 2, 2004 (JP) 2004-350467
Dec. 2, 2004 (JP) 2004-350468

(51) Int. Cl. H01L 41/08

(52) U.S. Cl. 310/328

(57) ABSTRACT

An enclosure of a cellular phone is formed with a plurality of sound releasing holes. The inside of a portion where the sound releasing holes are provided defines an air chamber formed with a receiving portion for mounting a piezoelectric sounding element. The piezoelectric sounding element is of bimorph structure formed by adhering piezoelectric elements on both surfaces of a diaphragm, and serves as a speaker by hermetically fixing a peripheral edge of the diaphragm to the receiving portion. Acoustic characteristics of such a piezoelectric sounding body relates to the total sum S of side surface areas of the sound releasing holes. Therefore, by setting the total sum to a value from 1.5 mm to 60 mm², variations in resonant frequency and lowering of the sound pressure are prevented, and hence the required acoustic characteristics can be secured while realizing reduction of the thickness of the wall of the enclosure.

### BACKGROUND OF THE INVENTION

1. Field of the Invention

The field relates to a piezoelectric sounding body used in an electronic device such as a cellular phone and an acoustic part and, more specifically, to prevention of deterioration of acoustic characteristics in association with reduction of the thickness of the enclosure, and to prevention of deterioration of sound pressure characteristics in association with reduction of the thickness of the enclosure.

2. Description of the Related Technology

Piezoelectric sounding bodies (piezoelectric speakers or the like) are used widely as simple electric sound transducing means and, in particular in recent years, are used widely in the field of cellular phones. The general piezoelectric sounding body is used as a speaker by supporting a piezoelectric sounding element of unimorph type or bimorph type, and then fixing the peripheral edges of the case to an enclosure or the like of various devices. In this case, the periphery of the case is mounted via, for example, ring-shaped PORON, which is a high-density micro cell polyurethane foam product manufactured by Rogers-INOAC Corporation, for preventing oscillations of the piezoelectric sounding element from being transmitted to the enclosure more than necessary. A piezoelectric sound transducing device disclosed in JP-A-7-107594 (pp. 3, see FIG. 1) is an example of the related art as described above. According to the related art described above, the case to which the piezoelectric element is attached is mounted to a housing via a cushion material such as a rubber ring.

According to the related art as described above, since a mounting height with the intermediary of the cushion material such as PORON increases, it is disadvantageous for the mobile devices with increasing demand for further miniaturization in these years. Also, in general, since the piezoelectric sounding element being supported by a supporting member (such as a case) is mounted to the enclosure, the height of the supporting member may prevent further reduction of the thickness of the enclosure. Therefore, reduction of the thickness itself can be realized by making the enclosure support the piezoelectric sounding element directly without using the cushion material or the case. However, since the cushion material described above prevents oscillations of the piezoelectric sounding element from being transmitted to the enclosure more than necessary, when the piezoelectric sounding element or the case supporting the same is mounted directly to the enclosure, the acoustic characteristics may disadvantageously be deteriorated. Also, when the piezoelectric sounding element is mounted directly to the enclosure, the sound pressure characteristics may be deteriorated by oscillations.

### SUMMARY OF THE INVENTION

In view of such circumstances, it is a first object of the invention to provide a piezoelectric sounding body and an electronic device in which deterioration of the acoustic characteristics in association with reduction of the thickness of the enclosure can be restrained.

It is a second object of the invention to provide a piezoelectric sounding body and an electronic device in which deterioration of the sound pressure characteristics in association with reduction of the thickness of the enclosure can be restrained.

In order to achieve the above-described objects, a piezoelectric sounding body in the invention is firstly a piezoelectric sounding body in which a periphery of a piezoelectric sounding element is supported by an enclosure having at least one sound releasing hole so as to define an air chamber with an inner surface of the enclosure, wherein the total sum of side surface areas of the sound releasing holes is from 1.5 mm² to 60 mm² with both values included.

Another aspect of the invention is a piezoelectric sounding body in which a periphery of a piezoelectric sounding element is supported by an enclosure having at least one sound releasing hole so as to define an air chamber with an inner surface of the enclosure, characterized in that the piezoelectric sounding element is fixed to the enclosure without the intermediary of a shock absorbing member, and the total sum of side surface areas of the sound releasing holes is from 1.5 mm² to 60 mm² with both values included.

Preferably, the air chamber is provided in the wall of the enclosure. Preferably, the enclosure is formed with a receiving portion for directly supporting a periphery of the piezoelectric sounding element or the piezoelectric sounding element is supported by a supporting member and a periphery of the supporting member is fixed to the enclosure. Preferably, the supporting member is formed with at least one sound releasing hole on a main surface thereof and the total sum of the side surface areas of the sound releasing holes is from 1.5 mm² to 60 mm² both values included. Preferably, the sound releasing hole has a substantially cylindrical shape.

In order to achieve the above-described objects, a piezoelectric sounding body in the invention is secondly piezoelectric sounding body in which a periphery of a piezoelectric sounding element is supported by an enclosure having a sound releasing hole so as to define an air chamber within an inner surface of the enclosure, characterized in that an overlapped width between the periphery of the piezoelectric sounding element and the enclosure side is 2 mm at the maximum.

A piezoelectric sounding body of another aspect of the invention is a piezoelectric sounding body in which a periphery of a piezoelectric sounding element is supported by an enclosure having a sound releasing hole so as to define an air chamber with an inner surface of the enclosure, characterized in that the piezoelectric sounding element is fixed to the enclosure without the intermediary of a shock absorbing member, and an overlapped width between the periphery of the piezoelectric sounding element and the enclosure side is 2 mm at the maximum.

Preferably, the air chamber is provided in the wall of the enclosure. Preferably, the enclosure is formed with a receiving portion for directly supporting a periphery of the diaphragm of the piezoelectric sounding element.

An electronic device in the invention is characterized in that the enclosure is provided with any one of the above-described piezoelectric sounding bodies. The objects, characteristics and advantages of the invention will be clear from detailed description shown below and the attached drawings.

First, according to the invention, with a piezoelectric sounding body in which a periphery of a piezoelectric sounding element is supported by an enclosure having at least one sound releasing hole so as to define an air chamber within an inner surface of the enclosure, characterized in that the piezoelectric sounding element is fixed to the enclosure and the total sum of side surface areas of the sound releasing holes is from 1.5 mm² to 60 mm² both values included, variations in resonant frequency and lowering of the sound pressure can be restrained, and required acoustic characteristics can be secured.

Second, according to the invention, with a piezoelectric sounding body in which a periphery of a piezoelectric sounding element is supported by an enclosure having at least one sound releasing hole so as to define an air chamber within an inner surface of the enclosure, characterized in that the piezoelectric sounding element is fixed to the enclosure and an overlapped width between the periphery of the piezoelectric sounding element and the enclosure side is 2 mm at the maximum, deterioration of the sound pressure characteristics due to oscillation of the enclosure is restrained and required acoustic characteristics can be secured.

### BRIEF DESCRIPTION OF THE DRAWINGS

FIG. 1 is a drawing showing a first embodiment of the invention, in which FIG. 1A is an end view of a principal portion of this embodiment, and FIG. 1B is an enlarged perspective view of a sound releasing hole of an enclosure;

FIG. 2 is a drawing showing a relation between the total sum of side surface areas of the sound releasing holes and the sound pressure in the first embodiment;

FIG. 3 is a drawing showing a relation between the total sum of the side surface areas of the sound releasing holes and the resonant frequency in the first embodiment;

FIG. 4 is a drawing showing a relation between the total sum of the side surface areas of the sound releasing holes and a Q value in the first embodiment;

FIG. 5 is a drawing showing another example of the invention;

FIG. 6 is an end view of a principal portion of a second embodiment and a modification thereof of the invention;

FIG. 7 is a drawing showing a relation between the frequency and the amplitude of a piezoelectric sounding body in the second embodiment;

FIG. 8 is a drawing showing a relation between the frequency and the sound pressure of the piezoelectric sounding body in the second embodiment; and

FIG. 9 is a drawing showing a relation between an overlapped width between the enclosure and a mounted section of a diaphragm and a dip depth of the sound pressure.

### DESCRIPTION OF THE PREFERRED EMBODIMENTS

Preferred embodiments for carrying out the invention will be described in detail on the basis of the embodiments.

### First Embodiment

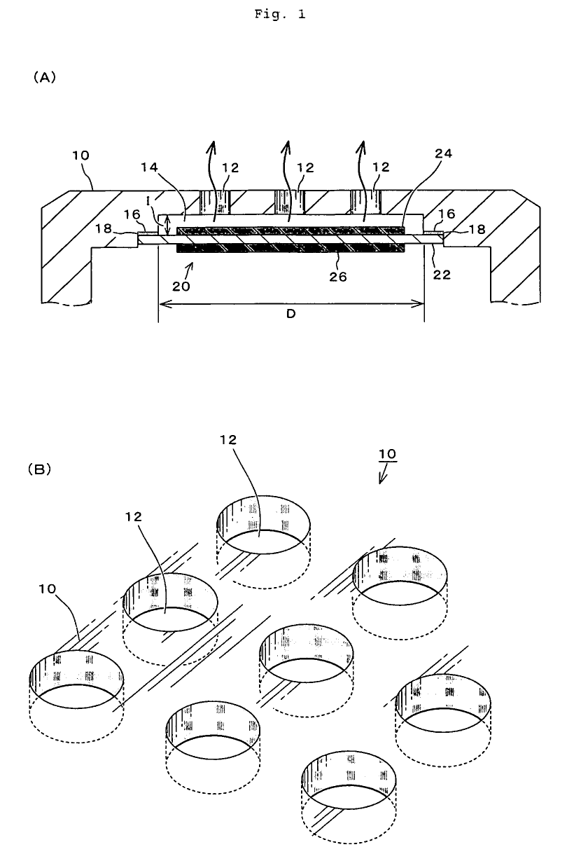

Referring first to FIG. 1 to FIG. 4, a first embodiment of the invention will be described. FIG. 1A is an end view of a principal portion of this embodiment, and FIG. 1B is an enlarged view of a sound releasing hole of an enclosure. In this embodiment, a piezoelectric sounding body in the invention is used as a speaker for a cellular phone. As shown in FIG. 1, an enclosure 10 of a cellular phone is formed with a plurality of sound releasing holes 12. An inside of the portion where the sound releasing holes 12 are provided defines an air chamber 14 formed with a receiving portion 16 for mounting a piezoelectric sounding element 20. The material of the enclosure 10 as described above is, for example, aluminum having a thickness of approximately 1 to 2 mm.

The piezoelectric sounding element 20 is of a bimorph type having piezoelectric elements 24, 26 adhered on both surfaces of a diaphragm 22 formed of metal or the like, and the piezoelectric elements 24, 26 have a laminated structure having piezoelectric bodies and electrode layers laminated alternately. Although the bimorph type is employed in the example shown in the drawings, it is also possible to employ a unimorph type having the piezoelectric element 24 or 26 on one of the surfaces of the diaphragm 22. The piezoelectric element 20 in this structure is hermetically fixed by adhering the periphery of the diaphragm 22 to the receiving portion 16 of the enclosure 10 with appropriate means such as an adhesive agent 18. At this time, a distance I between the surface of the diaphragm 22 and an upper surface of the air chamber 14 is set, for example, to 850 μm at the maximum, more preferably 300 μm at the maximum so as to be close to the amplitude of the piezoelectric sounding element 20 in the direction of the thickness thereof. The piezoelectric body, the electrode layer, and the adhesive agent described above may be those in the known type.

On the other hand, the relation with the surface area which comes into contact with airflow, that is, the relation with the side surface areas of the sound releasing holes 12 is very important for the acoustic characteristics of the piezoelectric sounding body. Therefore, the required acoustic characteristics can be obtained by defining the side surface areas of the sound releasing holes 12 to suitable values. In this embodiment, since the plurality of sound releasing holes 12 are provided, the influence of a total sum S of the side surface areas thereof to the acoustic characteristics will be inspected. The total sum S of the side surface areas are determined by the thickness of the enclosure 10, the diameters of the sound releasing holes 12, and the number of the sound releasing holes 12. The relation between the total sum S of the side surface areas and the sound pressure, resonant frequencies f₀, a Q value (an inverse number of the frequency difference when increased by 3 dB in the vicinity of the resonant frequency) will be described in sequence. Here, a diameter D of a movable portion of the diaphragm 22, that is, characteristic values are measured about three samples in which the distances between the receiving portions 16 in cross section shown in FIG. 1A are 18 mm, 21 mm, and 23 mm, respectively.

FIG. 2 is a drawing showing a relation between the total sum S of the side surface areas of the sound releasing holes 12 and the sound pressure, in which the horizontal horizontal axis represents the total sum S (mm²) of the side surface areas and the vertical axis represents the sound pressure (dB) respectively. The horizontal horizontal axis is logarithmically scaled. As shown in FIG. 2, the larger the total sum S of the side surface areas of the sound releasing holes 12, the higher the sound pressure becomes. Considering that the required condition of acoustic characteristics is 90 dB or higher in sound pressure (SPL: Sound Pressure Level), it is understood that the total sum S of the side surface areas may be about 0.3 mm² or higher in any diameters D. It is proved, by comparing the acoustic characteristics for each diameter and the total sum S of the side surface areas, that the acoustic characteristics are the same irrespective of the diameter D of the movable portion.

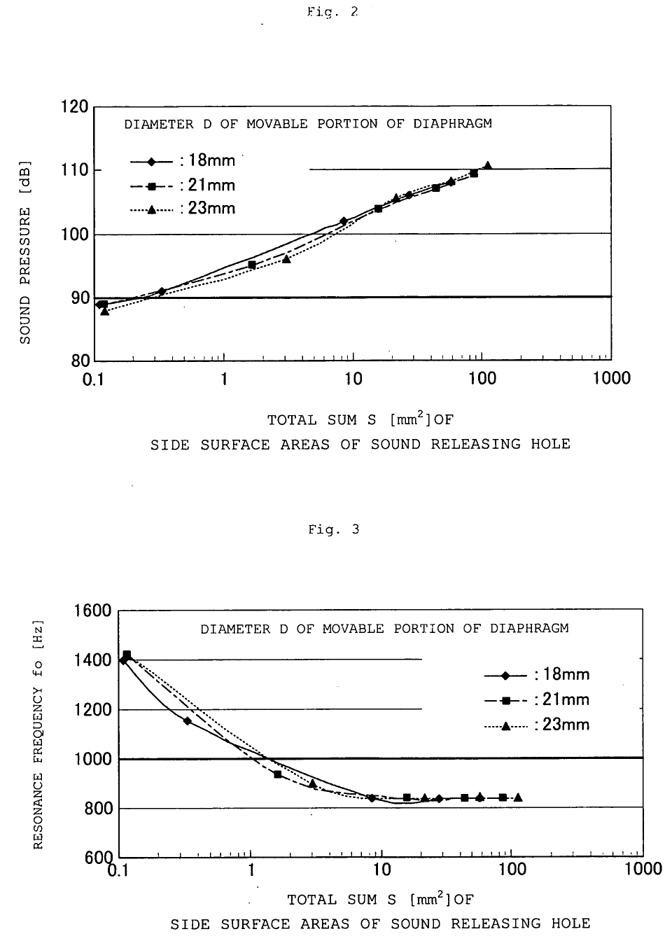

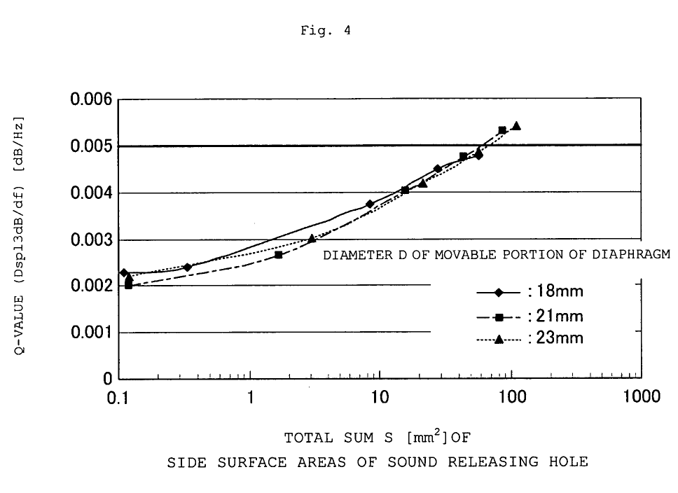

FIG. 3 is a drawing showing a relation between the total sum S of the side surface areas and the resonant frequency f₀. The horizontal axis represents the total sum S (mm²) of the side surface areas and the vertical axis represents the resonant frequency f₀ (Hz). The horizontal axis is logarithmically scaled. As is understood from FIG. 3, the resonant frequency f₀ undergoes a transition toward the higher frequency as the total sum S of the side surface areas of the sound releasing holes 12 decreases. Considering that the required condition of the acoustic characteristics in the resonant frequency f₀ is 1000 Hz or higher, it is understood that the total sum S of the side surface areas may be 1.5 mm² or larger for any diameters D.

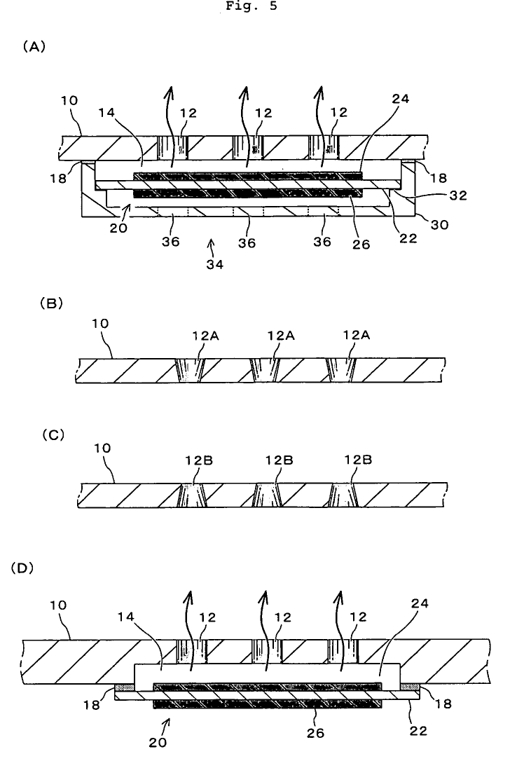

FIG. 4 is a drawing showing a relation between the total sum S of the side surface areas and the Q value, and the horizontal axis represents the total sum S (mm2) of the side surface areas and the vertical axis represents the Q value (the inverse number of the frequency difference when increased by 3 dB in the vicinity of the resonant frequency) (dB/Hz). The horizontal axis is logarithmically scaled. As is understood from FIG. 4, the smaller the total sum S of the side surface areas of the sound releasing holes 12, the smaller the Q value becomes. Considering that the required condition of acoustic characteristics is 0.005 at the maximum in the Q value, it is understood that the total sum S of the side surface areas may be 60 mm² at the maximum for any diameters D.

From the description described above, it is seen that the total sum S of the side area surfaces is preferably:
(1) 0.3 mm² or larger from the viewpoint of the sound pressure;
(2) 1.5 mm² or larger from the viewpoint of the resonant frequency; and
(3) 60 mm² at the maximum from the viewpoint of the Q value.

Therefore, since the lower limit of the total sum S of the side surface areas is determined by the resonant frequency, and the upper limit is determined by the Q value, the required acoustic characteristics can be secured by satisfying the relation;
1.5 mm²≦total sum S of the side surface area≦60 mm²

By adjusting the thickness of the enclosure 10, the number of sound releasing holes 12, and the diameters of the sound releasing holes 12, the total sum S of the side surface areas can be set within the above-described range.

In this manner, according to the first embodiment, since the piezoelectric sounding element 20 formed by adhering the piezoelectric elements 24, 26 to the both surfaces of the diaphragm 22 is fixed to the enclosure 10 without the intermediary of the shock absorbing member (cushion material) and the total sum S of the side surface areas of the sound releasing holes 12 formed on the enclosure 10 is set to be from 1.5 mm² to 60 mm² both values included, variations in resonant frequency and lowering of the sound pressure can be restrained and the required acoustic characteristics can be secured advantageously while realizing reduction of the thickness of the enclosure when being mounted.

In addition, when the total sum S of the side surface areas is set to 7 mm² or larger, the high sound pressure of 100 dB or higher can be obtained, and at the same time, the resonant frequency can be restrained to the 800's Hz. When the total sum S of the side surface areas is set to 15 mm² at the maximum, 0.004 or lower Q value can be obtained. Therefore, the more preferable range of S will be:
(1) 7 mm²≦total sum S of the side surface areas≦60 mm ²
(2) 1.5 mm²≦total sum S of the side surface areas≦15 mm²; or
(3) 7 mm²≦total Sum S of the side surface areas≦15 mm²

The invention is not limited to the above-described embodiment, and various modifications may be made without departing from the scope of the invention. For example, the following modifications are also available.

The shape, size and material shown in the above-described embodiment are illustrative only, and these values may be changed as needed as long as the total sum S of the side surface areas is set to a value within the above-described range.

Although the diaphragm 22 of the piezoelectric sounding element 20 is directly mounted to the enclosure 10 in the first embodiment described above, as shown in FIG. 5A, it is also possible to mount the piezoelectric sounding element 20 to a supporting member 30 provided with a stepped receiving portion 32 to fabricate a module 34, and then mount the periphery of the module 34 to the inner side of the enclosure 10. In this case, reduction of the thickness of the enclosure can be realized by an amount corresponding to the thickness of the shock absorbing member such as PORON in comparison with the related art. It is also possible to provide sound releasing holes 36 whose side surface areas are defined in the same manner as the sound releasing holes 12 in the first embodiment described above on the bottom surface of the supporting member 30. In addition, although the stepped receiving portion 16 is provided in the air chamber 14 in the above-described embodiment, it is also shown as an example, and as shown in FIG. 5D, the periphery of the diaphragm 22 may be directly fixed to the peripheral edge of the air chamber 14 by adhesive agent 18 or the like.

The number or arrangement of the sound releasing holes 12 shown here is also illustrative only, and may be changed as needed. Although the sound releasing holes 12 each has a substantially cylindrical shape in the first embodiment shown above, it is also possible to form the sound releasing holes so as to increase in diameter outwardly of the enclosure 10 as sound releasing holes 12A shown in FIG. 5B, or to form the same so as to increase in diameter inwardly of the enclosure 10 as sound releasing holes 12B shown in FIG. 5C. In either case, the same effects as in the first embodiment are achieved as long as the total sum of the side surface areas of the sound releasing holes satisfies the above-described range.

The piezoelectric sounding element 20 in the above-described embodiment is also illustrative only and may be of the unimorph type. The number of layers of the piezoelectric bodies and the electrode layers of the piezoelectric elements 24, 26 are also arbitrary, and may be increased or decreased as needed.

The application of the piezoelectric sounding body in the invention is also illustrative only, and may be applied as various electronic acoustic devices, communication devices, electronic devices, or components thereof.

### Second Embodiment

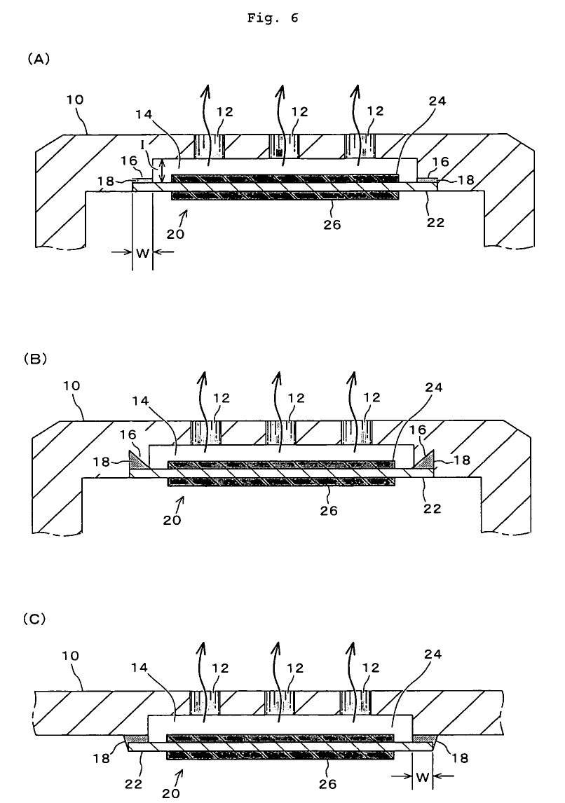

Referring now to FIG. 6 to FIG. 9, a second embodiment of the invention will be described. FIG. 6A is an end view of a principal portion of this embodiment, FIGS. 6B and 6C are drawings showing modifications thereof. In this embodiment, the piezoelectric sounding body in the invention is applied as a speaker for a cellular phone. As shown in FIG. 6A, the enclosure 10 of the cellular phone is formed with the plurality of sound releasing holes 12. The inside of the portion where the sound releasing holes 12 are provided defines the air chamber 14 formed with the receiving portion 16 for mounting the piezoelectric sounding element 20. The material of the enclosure 10 as described above is, for example, aluminum having a thickness on the order of 1 to 2 mm.

The piezoelectric sounding element 20 is of the bimorph type having piezoelectric elements 24, 26 adhered on both surfaces of the diaphragm 22 formed of metal or the like, and the piezoelectric elements 24, 26 have a laminated structure having piezoelectric bodies and electrode layers laminated alternately. Although the bimorph type is employed in the example shown in the drawings, it is also possible to employ the unimorph type having the piezoelectric element 24 or 26 on one of the surfaces of the diaphragm 22. The piezoelectric element 20 in this structure is hermetically fixed by adhering the periphery of the diaphragm 22 to the receiving portion 16 of the enclosure 10 with, for example, silicon adhesive agent 18. At this time, the overlapped width between the receiving portion 16 and the diaphragm 22 is set to be about 2 mm at the maximum as will be described later. The distance I between the surface of the diaphragm 22 and the upper surface of the air chamber 14 is set, for example, to 850 μm at the maximum, more preferably 300 μm at the maximum so as to be close to the amplitude of the piezoelectric sounding element 20 in the direction of the thickness thereof. The piezoelectric body, the electrode layer, and the adhesive agent described above may be those in the known type.

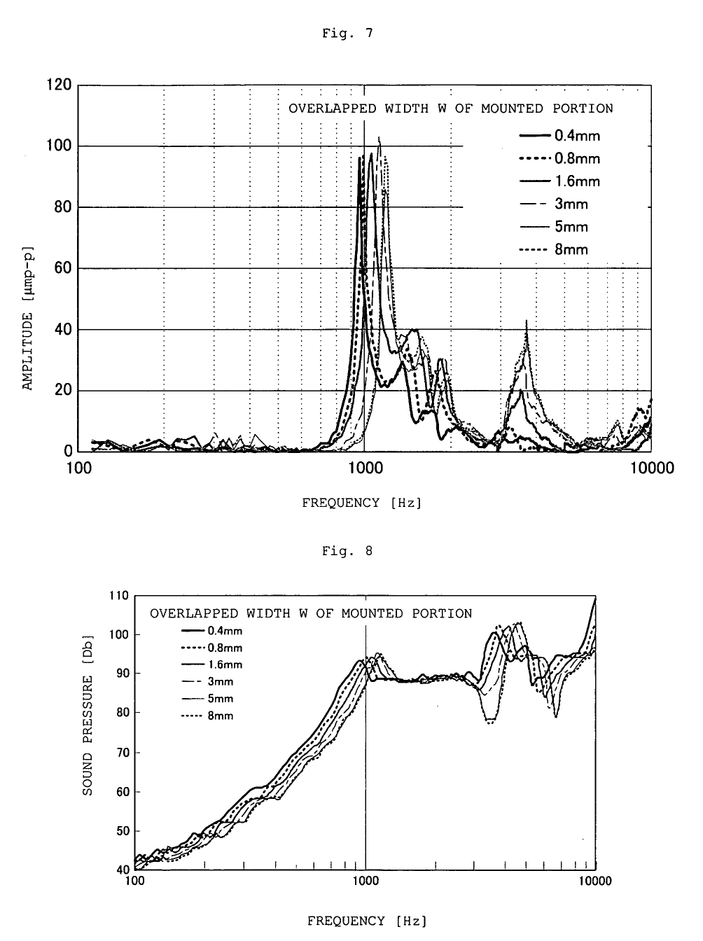

On the other hand, since the extent of transmission of oscillation from the piezoelectric sounding element 20 to the enclosure 10 changes depending on the extent of contact between the piezoelectric sounding element 20 and the enclosure 10, the sound pressure characteristics of the piezoelectric sounding body may be considered to have a relation with the overlapped width thereof. FIG. 7 shows a relation between the frequency and the amplitude when the overlapped width between the diaphragm 22 of the piezoelectric sounding element 20 and the receiving portion 16 of the enclosure 10, that is, an overlapped width W of the mounted portion is varied to 0.4 mm, 0.8 mm, 1.6 mm, 3 mm, 5 mm, and 8 mm. In FIG. 7, the horizontal axis represents the frequency (Hz), and the vertical axis represents the amplitude (μ mp-p). FIG. 8 is a drawing showing a relation between the frequency and the sound pressure with the overlapped width W as in FIG. 2, in which the horizontal axis represents the frequency (Hz) and the vertical axis represents the sound pressure (dB). The horizontal axes in FIG. 7 and FIG. 8 are both logarithmically scaled. As shown in FIG. 7, the magnitude of oscillation of the enclosure 10 changes characteristically with the change of the overlapped width W of the mounted portion. FIG. 8 shows the effect of the oscillation of the enclosure. As is understood from this drawing, a significant dip and deterioration of the sound pressure characteristics occur at frequencies which cause the enclosure to oscillate significantly.

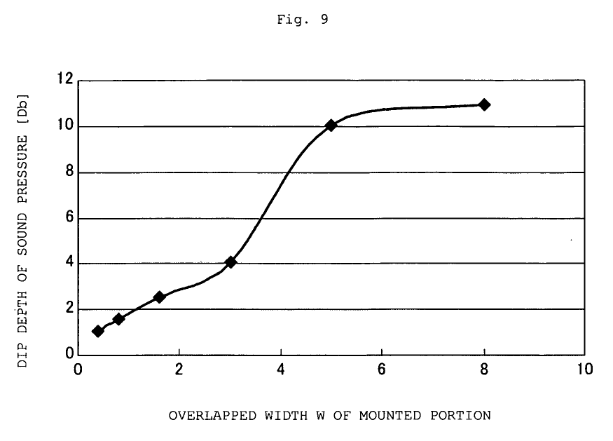

FIG. 9 shows a relation between the overlapped width W and the dip depth of the sound pressure. In FIG. 9, the horizontal axis represents the overlapped width W (mm), and the vertical axis represents the dip depth (dB) of the sound pressure. As seen in the same drawing, the larger the overlapped width W, the larger the dip depth becomes, and the degree of deterioration of the sound pressure characteristics increases. Considering that the allowable variations in sound pressure characteristics is up to about 3 dB, the deterioration of the sound pressure characteristics can be restrained by setting the overlapped width, that is, the width W of the mounted portion to 2 mm at the maximum, whereby the required acoustic characteristics can be secured. Furthermore, when the overlapped width W is set to 1.2 mm at the maximum, the dip depth can be reduced to 2 dB at the maximum.

As described thus far, according to the second embodiment, since the piezoelectric sounding element 20 having the piezoelectric elements 24, 26 adhered on the both surfaces of the diaphragm 22 is fixed to the enclosure 10 without the intermediary of the shock absorbing member (cushion material), and the overlapped width W between the diaphragm 22 of the piezoelectric sounding element 20 and the receiving portion 16 of the enclosure 10 is set to be 2 mm at the maximum, deterioration of the sound pressure characteristics due to the enclosure oscillation is restrained, and the required acoustic characteristics can be secured.

The invention is not limited to the embodiments described above, and various modifications may be made without departing from the scope of the invention.

The shape, size and material shown in the embodiments are illustrative only, and these values may be changed as needed as long as the overlapped width W is set to a value within the above-described range.

Although the receiving portion 16 for receiving the diaphragm 22 of the piezoelectric sounding element 20 is planar in the second embodiment described above, if the receiving portion 16 is inclined as shown in FIG. 6B, and the gap is filled with the adhesive agent 18, the same effects as in the example shown in FIG. 6A are achieved as long as the overlapped width of the portion which comes into contact with the diaphragm 22 is 2 mm at the maximum. Although the stepped receiving portion 16 is provided in the air chamber 14 in the first embodiment, it is also illustrative only, and the periphery of the diaphragm 22 may be adhered directly to the peripheral edge of the air chamber 14 using the adhesive agent 18 or the like as in the case shown in FIG. 6C. With such a structure as well, as long as the overlapped width W with respect to the diaphragm 22 is set to 2 mm at the maximum, the same effects as the above-described embodiments are achieved.

The number and arrangement of the sound releasing holes 12 are also illustrative only, and may be changed as needed.

The piezoelectric sounding element 20 in the above-described embodiments is also illustrative only, and the unimorph type may also be employed. The number of layers of the piezoelectric bodies and the electrode layers of the piezoelectric elements 24, 26 are also arbitrary, and may be increased and decreased as needed.

Since the piezoelectric sounding element is mounted to the enclosure, and the sum of the side surface areas of at least one or more sound releasing holes formed on the enclosure is set to be from 1.5 mm² to 60 mm² both value included, so that the variations in resonant frequency and lowering of the sound pressure are restrained to secure the required acoustic characteristics, the embodiments can be applied to the piezoelectric sounding body.

Since the piezoelectric sounding element is mounted to the enclosure and the width of the overlapped portion between the piezoelectric sounding element and the enclosure is set to 2 mm at the maximum, so that deterioration of the sound pressure characteristics due to the enclosure oscillation is restrained to secure the required acoustic characteristic, the embodiments can be applied to the piezoelectric sounding body.

In particular, the embodiments are suitable to be applied to the electronic devices or other components of various cellular phones in which reduction of the thickness of the enclosure when those devices or components are mounted is required, as well as other devices.

What is claimed is:

1. A speaker apparatus comprising:
a piezoelectric sounding element; and
an enclosure having one or more sound releasing holes proximate to said piezoelectric sounding element so as to define an air chamber with an inner surface of the enclosure,
wherein the total sum of side surface areas of the sound releasing holes is greater than or equal to 1.5 mm² and less than or equal to 60 mm².

2. A speaker apparatus, comprising:
a piezoelectric sounding element; and
an enclosure having one or more sound releasing holes proximate to said piezoelectric sounding element so as to define an air chamber with an inner surface of the enclosure,
wherein the piezoelectric sounding element is fixed to the enclosure without the intermediary of a shock absorbing member, and the total sum of side surface areas of the sound releasing holes is greater than or equal to 1.5 mm² and less than or equal to 60 mm².

3. The piezoelectric sounding body according to claim 1, wherein the air chamber is provided in the wall of the enclosure.

4. The piezoelectric sounding body according to claim 2, wherein the air chamber is provided in the wall of the enclosure.

5. The piezoelectric sounding body according to claim 1, wherein the enclosure is formed with a receiving portion for directly supporting a periphery of the piezoelectric sounding element.

6. The piezoelectric sounding body according to claim 2, wherein the enclosure is formed with a receiving portion for directly supporting a periphery of the piezoelectric sounding element.

7. The piezoelectric sounding body according to claim 1, wherein the piezoelectric sounding element is supported by a supporting member and the periphery of the supporting member is fixed to the enclosure.

8. The piezoelectric sounding body according to claim 2, wherein the piezoelectric sounding element is supported by a supporting member and the periphery of the supporting member is fixed to the enclosure.

9. The piezoelectric sounding body according to claim 7, wherein the supporting member is formed with at least one sound releasing hole on a main surface thereof and the total sum of side surface areas of the sound releasing holes is greater than or equal to 1.5 mm² and less than or equal to 60 mm².

10. The piezoelectric sounding body according to claim 8, wherein the supporting member is formed with at least one sound releasing hole on a main surface thereof and the total sum of side surface areas of the sound releasing holes is greater than or equal to 1.5 mm² and less than or equal to 60 mm².

11. The piezoelectric sounding body according to claim 1, wherein the sound releasing hole has a substantially cylindrical shape.

12. The piezoelectric sounding body according to claim 2, wherein the sound releasing hole has a substantially cylindrical shape.

13. A speaker apparatus comprising:
a piezoelectric sounding element; and
an enclosure having one or more sound releasing holes so as to define an air chamber with an inner surface of the enclosure and supporting the periphery of the piezoelectric sounding element,
wherein an overlapped width between the periphery of the piezoelectric sounding element and the enclosure side is 2 mm at the maximum.

14. A speaker apparatus comprising:
a piezoelectric sounding element; and
an enclosure having one or more sound releasing holes so as to define an air chamber with an inner surface of the enclosure and supporting the periphery of the piezoelectric sounding element,
wherein the piezoelectric sounding element is fixed to the enclosure without the intermediary of a shock absorbing member, and an overlapped width between the periphery of the piezoelectric sounding element and the enclosure side is 2 mm at the maximum.

15. The piezoelectric sounding body according to claim 13, wherein the air chamber is provided in the wall of the enclosure.

16. The piezoelectric sounding body according to claim 14, wherein the air chamber is provided in the wall of the enclosure.

17. The piezoelectric sounding body according to claim 13, wherein the enclosure is formed with a receiving portion for directly supporting the periphery of the piezoelectric sounding element.

18. The piezoelectric sounding body according to claim 14, wherein the enclosure is formed with a receiving portion for directly supporting the periphery of the piezoelectric sounding element.

19. An electronic device comprising the piezoelectric sounding body according to claim 1.

20. An electronic device comprising the piezoelectric sounding body according to claim 2.

21. An electronic device comprising the piezoelectric sounding body according to claim 13.

22. An electronic device comprising the piezoelectric sounding body according to claim 14.
